(19) United States
(12) Patent Application Publication
(10) Pub. No.: US 2014/0344642 A1
(43) Pub. Date: Nov. 20, 2014

(54) MODULATION/DEMODULATION METHOD, DEMODULATION APPARATUS, AND CODE MODULATION METHOD

(71) Applicants: Hitachi Consumer Electronics Co., Ltd., Tokyo (JP); Hitachi-LG Data Storage, Inc., Tokyo (JP)

(72) Inventor: Atsushi KIKUGAWA, Tokyo (JP)

(73) Assignees: Hitachi Consumer Electronics Co., Ltd., Tokyo (JP); Hitachi-LG Data Storage, Inc., Tokyo (JP)

(21) Appl. No.: 14/278,198

(22) Filed: May 15, 2014

(30) Foreign Application Priority Data
May 20, 2013 (JP) 2013-105742

(51) Int. Cl. H03M 13/00

(52) U.S. Cl. CPC H03M 13/6325
USPC 714/759

(57) ABSTRACT

Patterns that might be generated due to a burst error are prepared beforehand. These patterns are formed by shifting all “1”s in an original channel word. A list of these patterns generated as described above is retrieved in parallel with a general conversion table during demodulation. When the demodulation is interrupted due to the burst error, the result of the retrieval of the previous pattern is referred to, and when there is a hit, the error is regarded as the burst error of the original channel word, and the demodulation is continued.

### CROSS-REFERENCE TO RELATED APPLICATIONS

This application claims the priority of Japanese Patent Application No. 2013-105742, filed on May 20, 2013, which is incorporated herein by reference in its entirety.

### BACKGROUND OF THE INVENTION

1. Field of the Invention

The present invention relates to a modulation/demodulation method of a signal, a demodulation apparatus, and a code modulation method, and more particularly to a method of recording and reproducing information with high density by using light.

2. Description of the Related Art

Some terms in the description below are those used for Blu-ray (registered trademark) Disc (BD). These terms are likely to be described as another term in a system other than the BD. However, a person skilled in the art could have easily replaced these terms.

There are some systems for increasing a storage capacity of an optical disk. One of them is a code modulation described in U.S. Pat. No. 5,400,023 and JP-2003-273743-A. One type of the code modulation has already been used in BD. The code modulation is expected to bring some effects. The most expected one of these effects is to enhance a linear recording density. The one known as being used for this purpose is a run-length limit code.

In an optical disk, a diameter of an optical spot used for reproduction is far greater than physical resolution of a recording medium. Therefore, when binary data (referred to as user data in the present specification) to be recorded is recorded to correspond to a presence of a recording mark, symbol discrimination becomes rapidly difficult due to intersymbol interference between adjacent bits when an interval of bits to be recorded becomes smaller than the diameter of the optical spot. As a result, the resolution of the recording medium cannot effectively be utilized. On the other hand, in the run-length limit code, user data is recorded after being temporarily converted into a code string expressed by lengths of a mark and a space. In this case, even when the unit of the length of the mark and the space (channel bit length) is set smaller than that of the optical spot, the lengths of the mark and the space can be determined on a time axis during reproduction. It is supposed here that the shortest mark and the shortest space have a length equal to or longer than 2-channel bit in order to be reproduced with sufficient resolution. This system can realize higher linear recording density even by using an optical system having the same space resolution.

It is originally right that both the length of the recording mark and the length of the space are stated when recording is performed by using the run-length limit code. However, in the description below, only the mark will be stated in order to simplify the description, when the recording mark and the space are equivalently treated with no confusion being generated. For example, the expression of “the resolution of the shortest mark” means “the resolution of the shortest mark and the space”.

Two types are mainly known as the run-length limit code. One of them is a fixed length code based on an enumeration method, and the other is a variable length code. The run-length limit code used in BD that is the representative optical disk in recent days is a variable length code having the minimum run-length of 1, and this realizes the linear recording density 4/3 higher than the case where the code modulation is not carried out.

### SUMMARY OF THE INVENTION

The code modulation is used to realize some functions including a function of preventing an excessive consecution of 0 or 1 in addition to a function of enhancing the linear recording density. An optical disk places most emphasis on enhancement of a linear recording density by code conversion without decreasing a spot diameter, by using the run-length limit in the code modulation. 1-7PP code used in BD and having the minimum run-length of 1 realizes a linear density 4/3 higher than that in the case where the code modulation is not performed.

When an improvement rate of a linear recording density by the run-length limit code is defined as E (efficiency),

E=(d+1)C (1)

In this equation, d and C are the minimum run-length and capacity respectively. C is given as

C=log₂λ (2)

In this equation, X is the maximum real root of the characteristic equation described below.

Z^{k+2}−Z^{k+1}−Z^{k-d+1}+1=0 (3)

In this equation, k is the maximum run length. FIG. 2 illustrates the maximum E obtained when d is 1, 2, 3, or 4 based upon the above scheme. In BD, E is 4/3. Therefore, a combination of (d, k) that can realize E≧2 is needed to set the linear recording density 3/2 times higher than BD required for realizing 400 GB/disc. Specifically, d is required to be 4. The E obtained as described above is a theoretical value, and it is generally less than the theoretical value in the code modulation that is definable in actuality.

The code modulation is a mapping (conversion) that associates mi-bit code in a code string set A with ni-bit code in another code string set B in one-to-one correspondence (m, n, and i are natural numbers). A variable length coding and a fixed length coding by an enumeration method have been known as a practical code modulation system. In the variable length coding, an effective efficiency E* is given by the following equation.

E*=(d+1)m/n (4)

In this case, when E* is close to the theoretical value E, and a combination (particularly, m) of m and n that are sufficiently small natural numbers is present, the variable length coding is definable. The reason why m has to be a small natural number will be described later. In the cases of d=4 and E*=2, m=2 and n=5 satisfy this condition. It is to be noted that k has to be larger than 16 as is understood from FIG. 2. VFM (variable five modulation) has been known as an example of this coding system.

In a partial response system, an error is likely to occur in a pattern having smaller amplitude. Therefore, in the VFM developed so far, the number of consecutive occurrences of the shortest mark is suppressed to be not more than a certain number. In the partial response system, the patterns having a small difference in Euclidean distance are likely to be erroneously identified, but in a system such as BDXL in which 2T mark with resolution of 0 occurs, there are plural patterns whose erroneous determination is non-negligible, since they include 2T marks, even if the Euclidean distance difference is large. The similar phenomenon occurs in VFM when the length of the shortest mark is reduced to the length corresponding to the length of the shortest mark in BDXL. In the VFM, the mark length shortest next to 5T is 6T, and the difference in the resolution between 5T mark and 6T mark is small. Therefore, a more complicated and long burst error becomes a problem such as a pattern including 6T mark. The presence of the burst error described above brings the problems described below.
A) In a region where a short mark consecutively occurs, a burst error is caused with a length close to the length of the whole region because of one error, and the range of the influence of the first error is increased.
B) Since plural edges are simultaneously shifted, a channel bit pattern that is not listed in the conversion table occurs, with the result that a demodulation error is caused.

FIG. 3 illustrates one example of a conversion table of (4, 21) PP that is one of VFM. This is configured based upon the method described in JP-2003-273743-A. In the description below, the code modulation according to the table illustrated in FIG. 3 is referred to as (4, 21) PP.

FIG. 4 illustrates an example of a burst error observed in a reproduction simulation. Specifically, a reproduction signal is obtained by convolution with a channel bit pattern based upon an optical response acquired by the optical simulation. The channel bit pattern is formed by performing the (4, 21) PP code modulation to a random user data string. A calculation condition of the optical response is such that a wavelength of spot light is 405 nm, and NA of an objective lens is 0.85. The channel bit length is defined as 22.3 nm. In this case, the shortest mark length is equal to the shortest mark length of BD XL. PR (1, 1, 1, 1, 1, 1, 1, 1, 1, 1, 1) ML is used as the reproduction channel.

FIG. 5 is a graph illustrating an occurrence frequency of burst errors observed in the simulation using the (4, 21) PP to a number of edges included in the burst error.

From a survey of the condition of occurrence of errors, it is found that a ratio of a single edge shift error is small, and there are many burst errors consecutively occurring, as expected. FIG. 5 illustrates a result of an examination of the condition of error occurrence focusing on the length of the burst error. A horizontal axis of the graph indicates a number of edges included in the burst error, and indicates a length of a burst. Accordingly, a single edge shift becomes 1, and the movement of the shortest mark becomes 2. As apparent from FIG. 5, the ratio of a single edge shift is small, and there are a lot of burst errors in the (4, 21) PP. The case where the number of consecutive errors is 2 is observed most.

FIG. 6 illustrates a process of recording and reproducing data. Notably, FIG. 6 is simplified by illustrating only a portion necessary for the description in the present specification. User data is firstly subject to code modulation with a code modulation system designated by a modulator 3. The output from the modulator is a bit stream data in NRZ (non return to zero) format. The bit stream data in the NRZ format is written such that the bit corresponding to a boundary of a mark is written as “1” and the other bits are written as “0”. This data is converted into NRZI (non return to zero inverted) format signal in which “1” and “0” respectively correspond to a mark and a space by an NRZI converter 101, and then, recorded on an optical disk 1 through an optical pickup 2.

During the reproduction of the data, the data is optically reproduced by the optical pickup 2, and converted into an electric signal. Intersymbol interference occurs during the optical reproduction, since a size of an optical spot is finite. A PRML decoder 5 decodes the channel bit string from the reproduction signal, while eliminating the intersymbol interference. The channel bit string obtained as a result of decoding is converted into an NRZ format from the NRZI format by using an NRZ converter 102. An output from the NRZ converter is demodulated into binary data by a demodulator 4. If an error or time lag does not occur during the process so far, the output from the demodulator 4 matches with the original user data.

The code modulation and demodulation are carried out by using the conversion table illustrated in FIG. 3. FIG. 7 illustrates the process. Specifically, a user bit stream 24 that is an element in a user bit stream set 20 is converted into a corresponding channel bit stream 25 in a channel bit stream set 22 in accordance with the conversion table during the modulation. The user bit stream set and the channel bit stream set are linked by one-to-one onto mapping. Specifically, the demodulation is the inverse mapping of the modulation. In order to establish the code modulation, it is necessary that a size of a channel bit stream candidate set is equal to or larger than the user bit stream set. In general, the channel bit stream candidate set is larger than the user bit stream set as illustrated in FIG. 7. Specifically, there are channel bit stream candidates not listed in the conversion table are present, which hereinafter referred to as excess bit stream 26. The set having the excess bit stream as an element is referred to as an excess bit stream set 23. Accordingly, when an error occurs during the reproduction process as illustrated in FIG. 7, the user bit stream set might be changed to the excess bit stream due to the error. In this case, the demodulation based upon the conversion table in FIG. 3 cannot be executed, so that an exception process is needed. This makes the demodulator complicated. In the above description, the variable length coding is used as an example. However, the same phenomenon also occurs in the fixed length conversion.

In the burst error, plural edges simultaneously move in the same direction. Therefore, in the variable length coding, it sometimes becomes impossible to identify a boundary of a channel word. In the variable length coding, a prefix pattern condition is used for identifying a boundary of a channel word during the demodulation. The prefix pattern condition means that a channel bit pattern shorter than a prefix bit pattern is not included on the head part of the channel bit pattern. FIG. 8 illustrates an example of an error in identifying a boundary of a channel word due to a burst error. The user bit stream 24 is “11 00 01 00” in this case, and this is converted into a channel bit stream of “00100 00010 00010 00000” by the (4, 21) PP modulation. The channel bit stream obtained by the decoding process after the recording and reproduction is returned to the user bit stream by referring to the conversion table. In this case, if the decoded channel stream does not include an error, each channel bit word boundary 30 is obviously identified correctly. It is supposed here that the bit stream is identified as “01000 00100 00100 00000” by the PRML decoder because of the burst error generated during the reproduction as illustrated in FIG. 8. In this case, the boundary of the channel bit word determined by referring to the conversion table is different from the boundary in the case where there is no error. The erroneous boundary is referred to as a false channel word boundary 31. A channel word split by the false channel word boundary is referred to as a false channel word 32. The result of the demodulation is naturally different from the result of the case where there is no error, and such demodulation result is referred to as a false user bit stream 33. It is a problem that the result of the demodulation is erroneous, but the most serious problem is that a channel word not listed in the conversion table occurs due to the erroneous identification of the channel word boundary, and hence, the demodulation becomes impossible. In this case, an exception process is needed. The erroneous identification of the channel word boundary might be continued afterward in a chain-reaction manner, resulting in that errors due to the demodulation might be generated in a wider range than the range of the burst error during the decoding. The erroneous identification of the channel word boundary described above is referred to as a boundary error below for simplifying the description. The phenomenon in which the boundary error is propagated backward is referred to as a boundary error propagation, and the phenomenon in which the demodulation process cannot be continued is referred to as a demodulation error.

In order to solve the above-mentioned problems, the correspondence from an element in an optional user bit stream set to an element in a channel bit stream set is unique in a conversion table referred to during the modulation, but plural elements that are sources of the correspondence to at least some of user bit stream set elements are present in a conversion table referred to during the demodulation. In this case, conversion tables that are asymmetric between the code modulation and demodulation are used for at least one of the plural elements that are the sources of the correspondence. More specifically, patterns that might be generated due to a burst error are preliminarily prepared. These patterns are generated by shifting all “1”s in an original channel word.

The list of the pattern created as described above is retrieved in parallel with a normal conversion table during the demodulation. More specifically, when the demodulation is interrupted due to a burst error, a supplementary pattern set having supplementary patterns, which are channel bit patterns generated as a result of the burst error, as elements is simultaneously retrieved, and when there is a hit, it is regarded as a burst error of the original channel word, whereby the demodulation is continued. When the demodulation error caused by the boundary error due to the burst error or the boundary error propagation occurs, a channel bit stream with a necessary length is transmitted to a boundary error pattern comparator, and this channel bit stream is compared to each boundary error pattern to try a return process.

In order to suppress the consecution of the short marks, an NRZ pattern in which a start end and a terminal end of a channel word with a length of 30 bits or more are “00000” is used.

A frequency of occurrence of a burst error that continues for a long time is reduced by using the modulation code and the modulation system according to the present invention. The present invention can also provide an optical disk drive that can return from a demodulation error caused by a burst error.

### BRIEF DESCRIPTION OF THE DRAWINGS

FIG. 1 is a diagram illustrating one example of embodying the present invention;

FIG. 2 is a graph illustrating k dependence of a recording density for each of the shortest run-length limits;

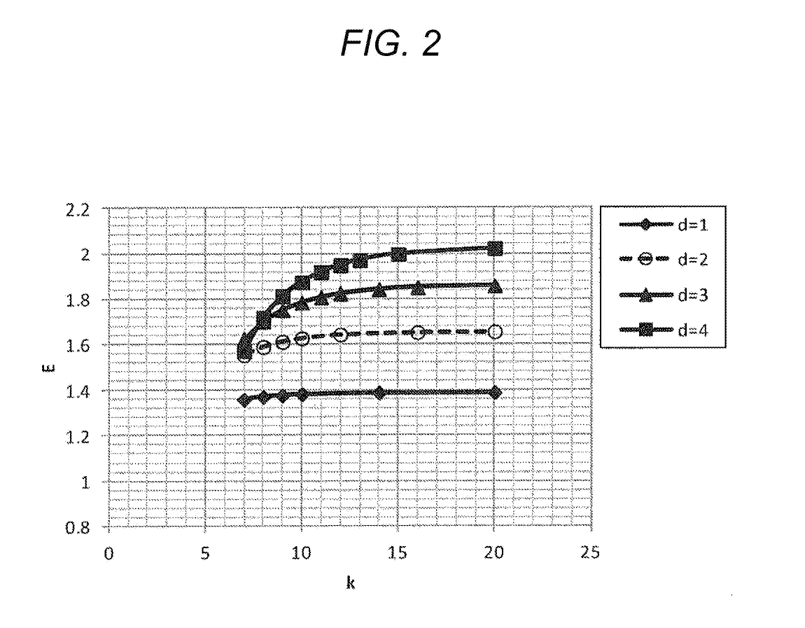

FIG. 3 is a conversion table of (4, 21) PP conversion that is one example of VFM;

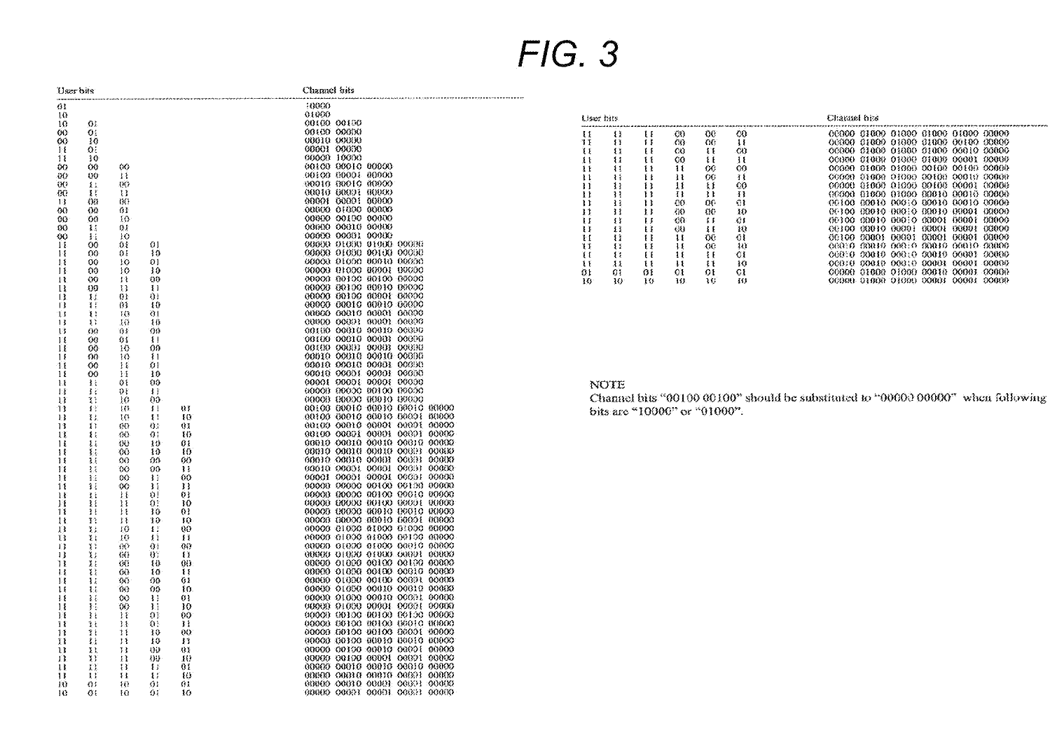

FIG. 4 is a diagram illustrating one example of a burst error;

FIG. 5 is a diagram illustrating one example of a distribution of a length of a burst error observed in a reproduction simulation of a signal recorded with (4, 21) PP modulation;

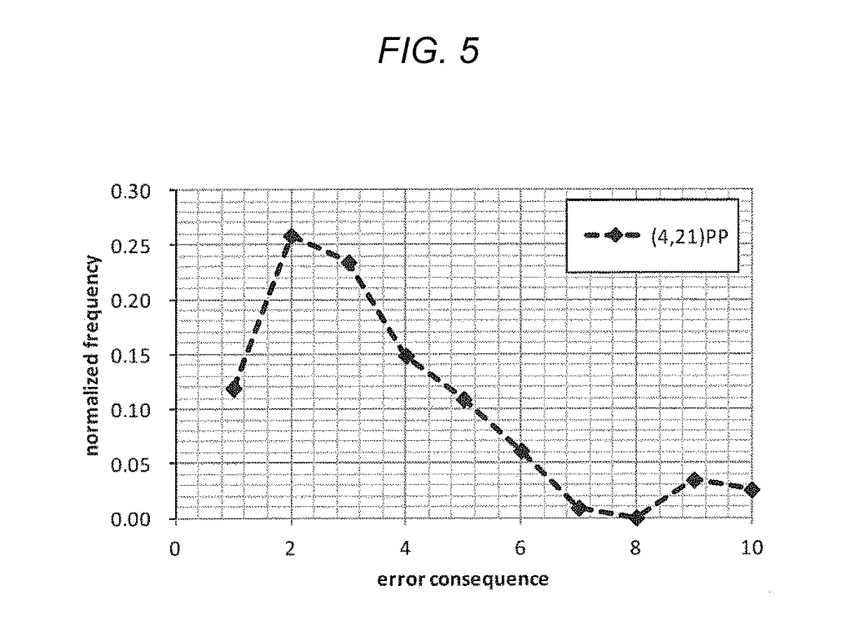

FIG. 6 is a diagram illustrating a recording/reproduction process of data;

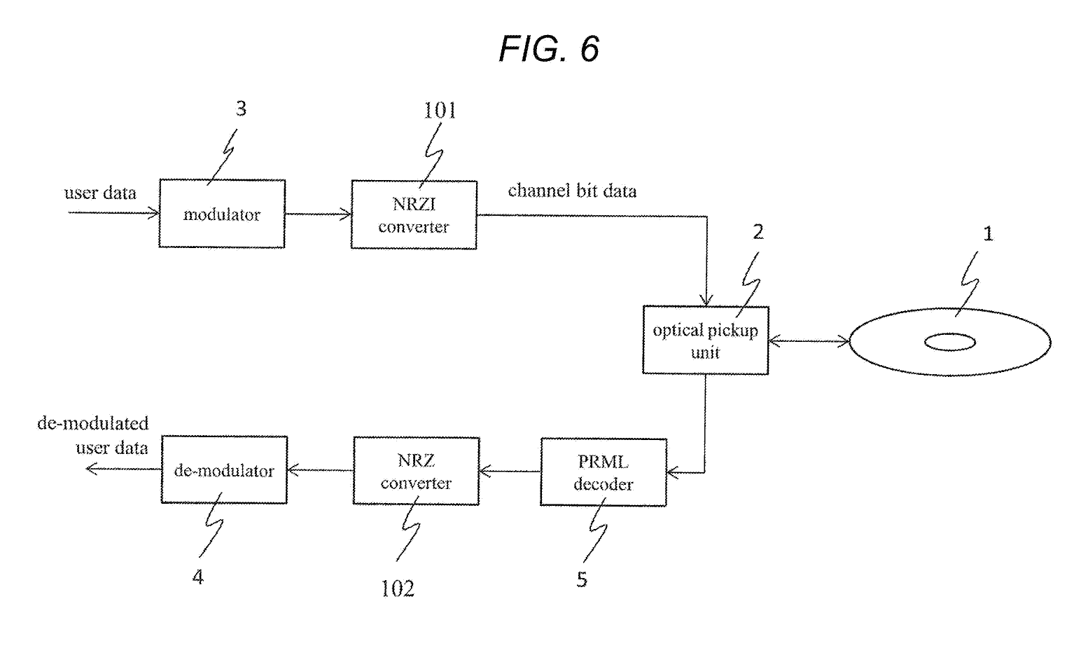

FIG. 7 is an explanatory view illustrating a case in which demodulation becomes impossible due to a burst error;

FIG. 8 is an explanatory view illustrating a case in which a channel word boundary is erroneously identified due to a burst error;

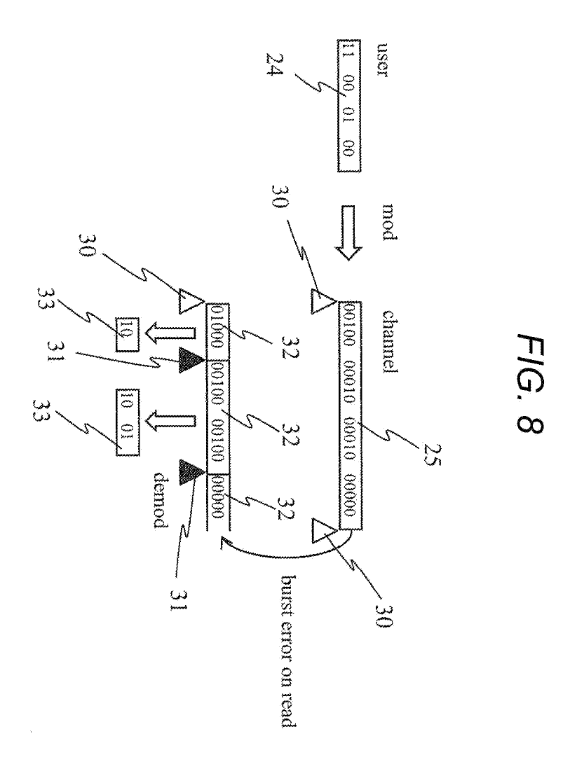

FIG. 9 is an explanatory view illustrating a demodulation principle in an asymmetric modulation and demodulation;

FIG. 10 is an explanatory view illustrating one example of an occurrence condition of a demodulation error;

FIG. 11 is an explanatory view illustrating one example of an occurrence condition of a boundary error propagation;

FIG. 12 is an explanatory view illustrating a demodulator that can recover a demodulation error;

FIG. 13 is a diagram illustrating one example of a conversion table for a code modulation that suppresses consecution of short marks;

FIG. 14 is a diagram illustrating one example of pattern replacement for suppressing consecution of short marks;

FIG. 15 is a diagram illustrating one example of a distribution of a length of a burst error observed during a reproduction simulation of a signal recorded with a code demodulation that suppresses consecution of short marks;

FIG. 16 is a diagram illustrating one example of an optical disk drive to which the present invention is applied;

FIG. 17 is an explanatory view of a demodulation process out of asymmetric modulation and demodulation using a supplementary pattern; and

FIG. 18 is an explanatory view of a process of recovering a demodulation error.

### DESCRIPTION OF THE PREFERRED EMBODIMENTS

### Asymmetric Modulation and Demodulation

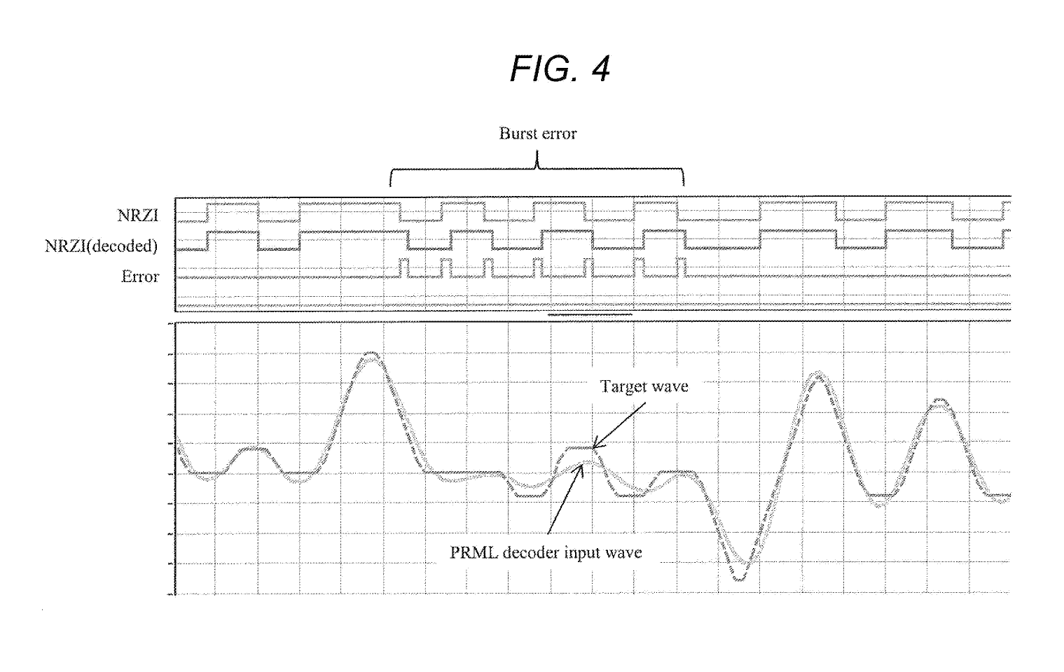

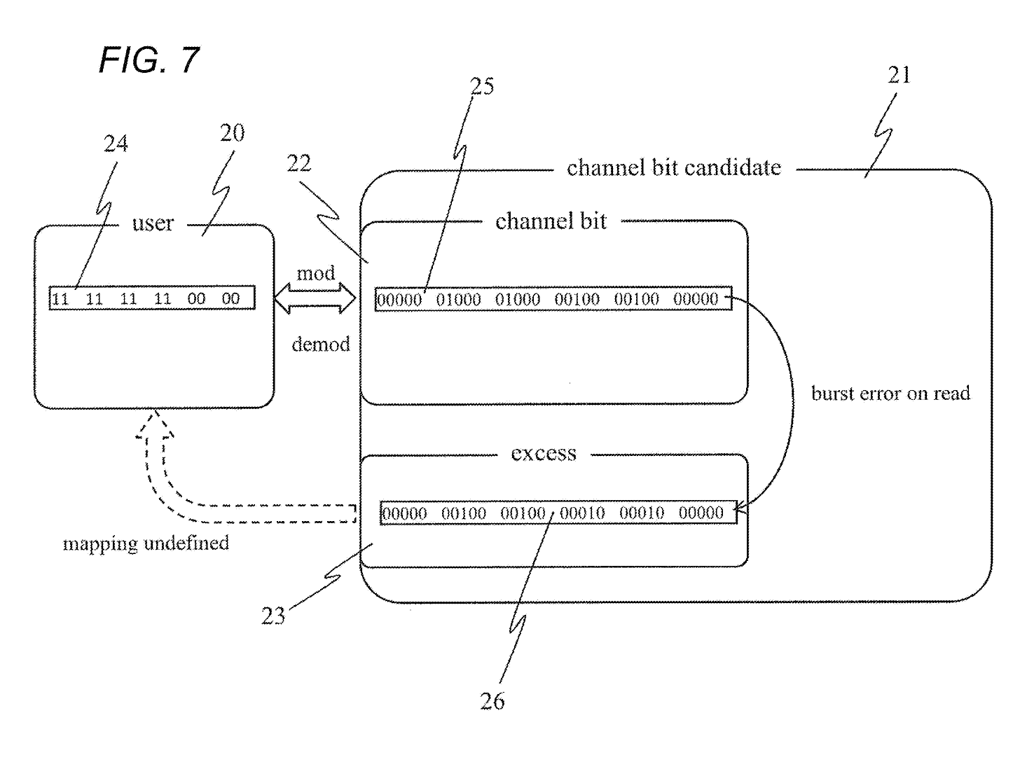

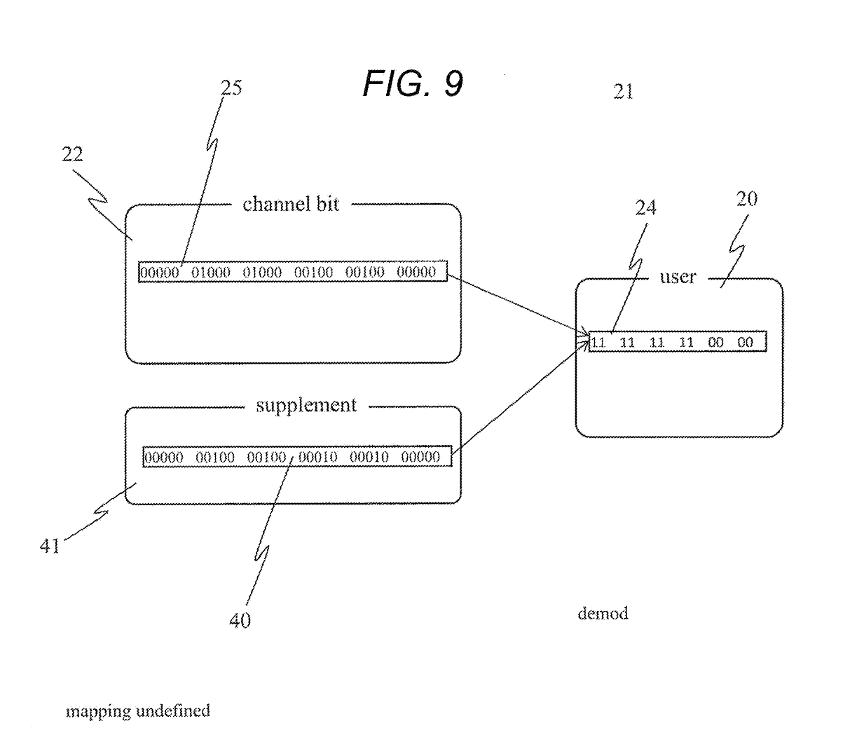

A countermeasure based upon the present invention against an occurrence of a demodulation error due to an occurrence of a burst error in the problems described above will be described. Firstly, an asymmetric conversion is used. This will be described with reference to FIG. 7 illustrating an example of a pattern. In this example, a burst error occurs in which all edges in a channel word are shifted to the right by 1 channel bit. If the channel bit pattern generated as a result of the burst error is listed in the conversion table, the demodulation process after this part can be continued, although the result of the demodulation includes an error. The problem is that the demodulation process cannot be continued since the channel bit pattern generated as a result of the burst error is not listed on the conversion table. In view of this, a supplementary pattern set 41 having a supplementary pattern 40, which is the channel bit pattern generated due to the burst error, as elements is simultaneously retrieved during the demodulation as illustrated in FIG. 9, in order to solve this problem. The supplementary pattern can be generated by applying a burst error mode, which is considered to be most likely to occur for each channel word. The correspondence to the original user bit stream from the supplementary pattern is defined in the conversion table applied to this supplementary pattern during the demodulation, whereby the interruption of the demodulation process can be avoided. It is also expected that the demodulation result is correct. However, if the supplementary pattern matches the other channel word, this pattern cannot be used as the supplementary pattern. The supplementary pattern also has to be an element of a channel bit stream candidate set. In VFM system such as (4, 21) PP, the burst error mode that is most likely to occur is the one in which plural edges are shifted by 1 bit at the same time in the same direction in a pattern including 5T mark and 6T mark as in the example in FIG. 4. The process of referring to asymmetric conversion tables in the modulation and demodulation is referred to as asymmetric modulation and demodulation (AMD).

A short channel word uses up almost the channel bit stream candidate set, so that there is little room for preparing the supplementary pattern. In (4, 21) PP, the case where the supplementary pattern can be prepared is limited to the case where the channel word length is 30.

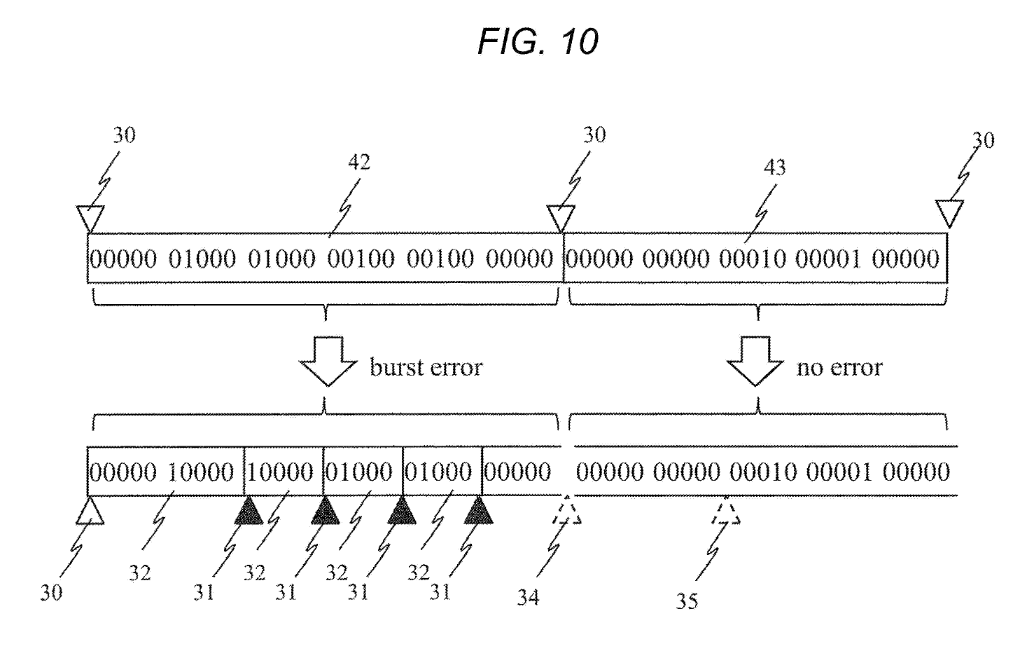

The state in which the above-mentioned simple asymmetric modulation and demodulation exhibit sufficient effects is limited to the case where the result of the burst error corresponds to the supplementary pattern. An additional measure is needed to the demodulation error and the boundary error propagation, which are caused by the boundary error due to the burst error as described above. FIG. 10 illustrates another example of the demodulation error. In this example, a burst error occurs in which all edges in a preceding channel word 42 are shifted to the left by 1 bit. As a result, when the preceding channel word is demodulated, this channel word is recognized as being split into plural false channel words. The last 5 bits of the preceding channel word are split by the false channel word boundary. “00000” is not listed in the conversion table. Therefore, when the channel bit length to be processed is increased to 10, “00000 00000” becomes a candidate. This pattern is the one for the exception process according to the definition of (4, 21) PP, and is effective only when the succeeding pattern is “10000” or “01000”. However, the succeeding pattern is also “00000”, so that the conversion table does not include the corresponding pattern. A supplementary pattern cannot be defined for the pattern in which “00000” is repeated three times from the head. Therefore, this becomes the demodulation error.

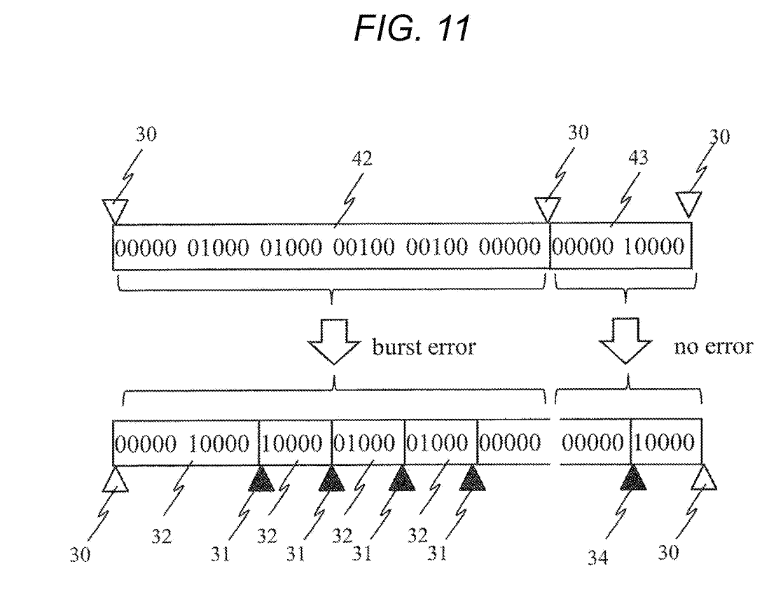

FIG. 11 illustrates an example of the boundary error propagation. The pattern of the preceding channel word and the error condition are the same as those in FIG. 10. Therefore, the example in FIG. 11 has the same condition in which the last pattern of the preceding channel word is split by the false channel word boundary and the succeeding channel word starts with “00000”. The different point from FIG. 10 is that “00000 00000” is determined to correspond to the exception since the last half of the succeeding channel word is “10000”. As a result, a new false channel word boundary is generated in the succeeding channel word. Specifically, the boundary error propagation occurs. Consequently, not only the demodulation result of the preceding channel word but also the demodulation result of the succeeding channel word whose decoding result does not include an error are erroneous. This can be regarded as one of error propagations. However, since the terminal pattern of the succeeding channel word is correctly recognized, the channel words afterward can correctly be determined, and no demodulation error occurs.

Why the demodulation error or the boundary error propagation described above occurs is because there is no system for recognizing and preventing the boundary error. This is because, in the demodulation process, abnormality cannot be sensed during when the channel bit stream listed in the conversion table is received. There is no system of directly sensing a boundary error. In view of this, the present invention aims to solve this problem by simultaneously retrieving a supplementary pattern in parallel with a pattern retrieval for demodulation.

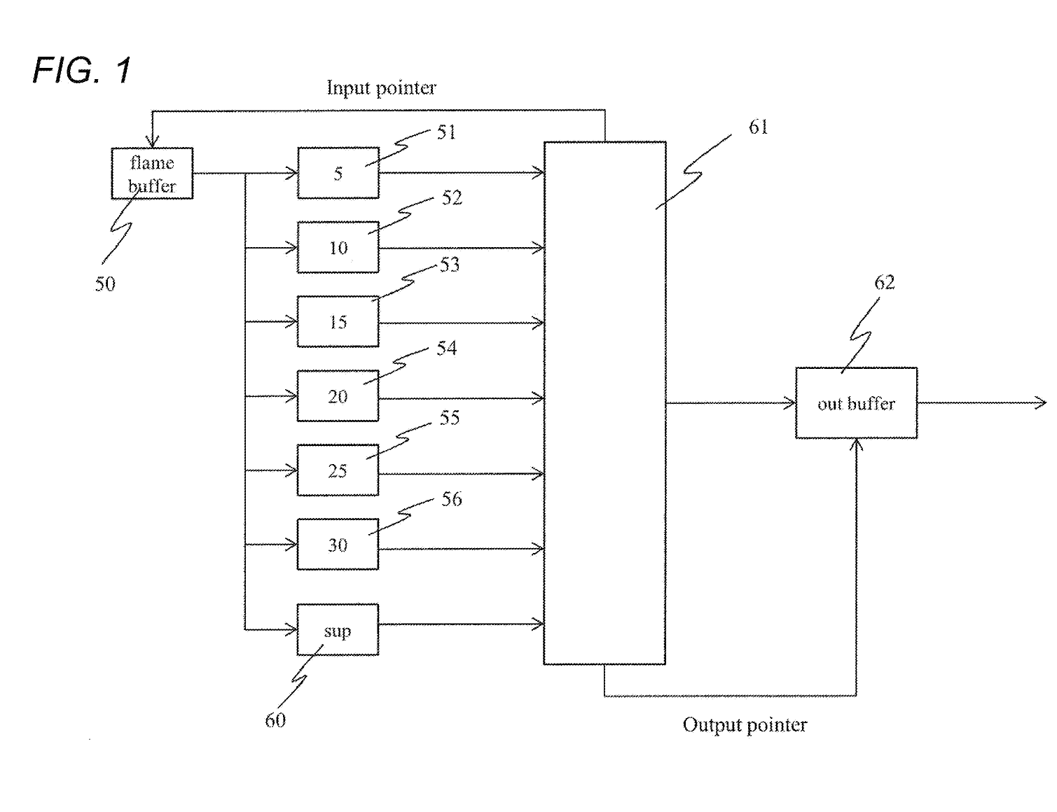

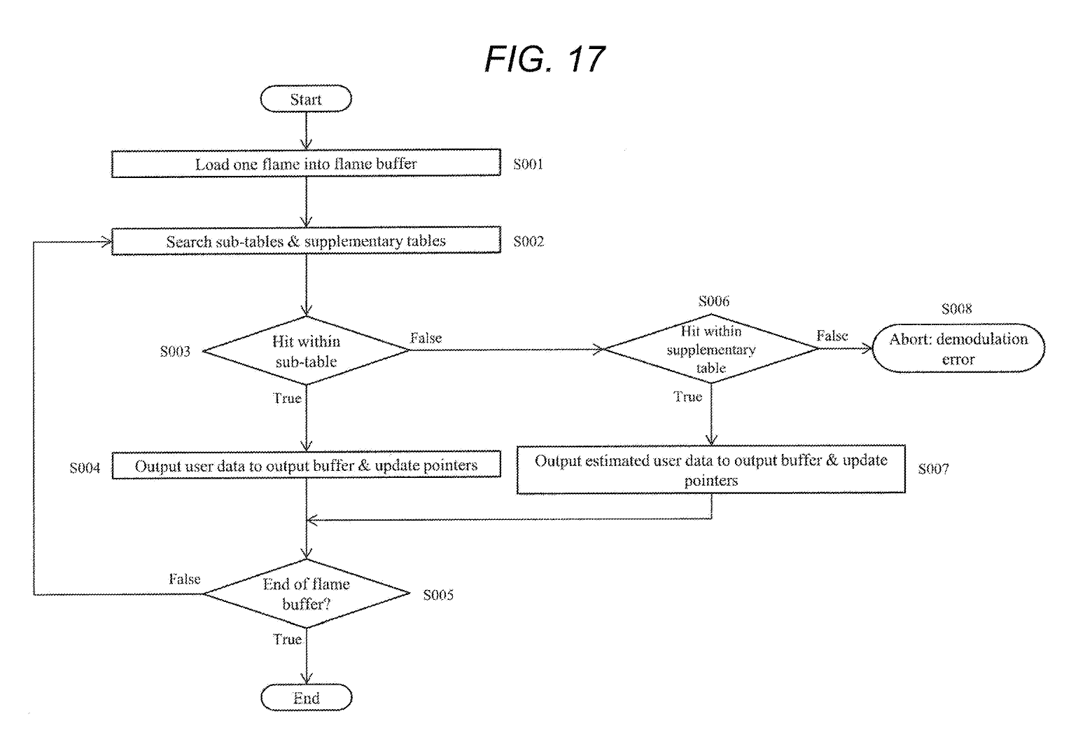

FIG. 1 illustrates one example of executing this system. This example is premised on (4, 21) PP. A configuration of a demodulator in FIG. 1 and a processing procedure in FIG. 17 will be simultaneously described below. The processing procedure is indicated by a symbol such as S001 in the figure.

The demodulation is executed for each frame. A person skilled in the art would have known that this is popular. An output from a PRML decoder converted into an NRZ format for one frame is held in a frame buffer 50 until the demodulation process for this frame is finished (S001). In the case of (4, 21) PP, the data in the frame has at a maximum of 30 bits. Therefore, the head position of the bit stream to be processed has to be indicated by an input pointer. The input pointer is calculated by a controller 61. An initial value is the head of the input buffer.

In order to execute the demodulation process, a conversion table that defines modulation by using the data in the frame buffer is retrieved. Specifically, it is checked whether the channel bit stream in the conversion table matches the data in the frame buffer (S002). In the example in FIG. 1, a retriever is prepared for each channel word length in the conversion table. Specifically, a bit stream with a length corresponding to the length in the conversion table held by each converter is transmitted, in other words, 5 bits are transmitted to a 5-bit retriever 51 holding a table in which the channel word length is 5 bits, and 10 bits are transmitted to a 10-bit retriever 52 holding a table in which the channel word length is 10 bits. The same applies to a 15-bit retriever 53, a 20-bit retriever 54, a 25-bit retriever 55, and a 30-bit retriever 56. Each retriever retrieves the holding conversion table, and determines whether the channel bit stream in the conversion table matches the inputted bit stream or not (S003). When the conversion table has a channel bit stream hitting the inputted bit stream, the retriever transmits a signal indicating that there is a channel bit stream matching the inputted bit stream to the controller 61 together with the corresponding channel bit stream. When the conversion table does not have a channel bit stream matching the inputted bit stream, the retriever transmits a signal indicating that there is no channel bit stream matching the inputted bit stream to the controller 61. When the decoding result does not include an error, there is a hit in any one of the retrievers for certain, and the output from the corresponding retriever is outputted to an output buffer 62 (S004). The output position in the output buffer is indicated by an output pointer outputted from the controller. After the output to the output buffer is finished, the values of the input pointer and the output pointer are updated according to the channel word length processed by the retriever having the hit. After the input pointer reaches the end of the input buffer, the process for this frame is ended (S005).

Next, a process when a burst error occurs, but a boundary error does not occur, and a pattern generated as a result of the burst error matches one of supplementary patterns will be described. In this case, a channel bit stream with a necessary length is transmitted to each retriever, and each retriever retrieves a conversion table, as in the case previously described. In this case, a pattern generated by the burst error keeps a prefix condition, so that a retrieval by each retriever holding a general conversion table of (4, 21) PP is executed (S003). However, in this case, there is no hit at all for the inputted pattern, and this is reported to the controller. On the other hand, a channel bit stream with a necessary length is simultaneously transmitted to a supplementary pattern comparator 60, and a result of the comparison between the channel bit stream and each supplementary pattern is examined (S006). In this case, since one of the supplementary patterns matches the inputted pattern, a signal indicating that there is a hit and the user bit stream associated with the matching supplementary pattern are transmitted to the controller. The process for the input and output pointers is the same as in the previous case (S007). The case in which there is no hit with the supplementary pattern means the demodulation error. Accordingly, the process is interrupted (S008).

The boundary error pattern will be described. The boundary error pattern can be generated from the channel word in the conversion table like the supplementary pattern. For example, the mode of the burst error that is more likely to occur is 1-bit shift. Therefore, in the example in FIG. 10, it is “00000 10000 10000 01000 01000 00000” or “00000 00100 00100 00010 00010 00000”. However, the latter corresponds to the supplementary pattern. On the other hand, the former does not satisfy the prefix condition as described above. The pattern that does not satisfy the prefix condition, i.e., the pattern that is not an element of the channel bit stream candidate set, is referred to as the boundary error pattern. The process of shifting all “1”s in the channel word in one direction to generate the boundary error pattern or the supplementary pattern is referred to as a burst shift.

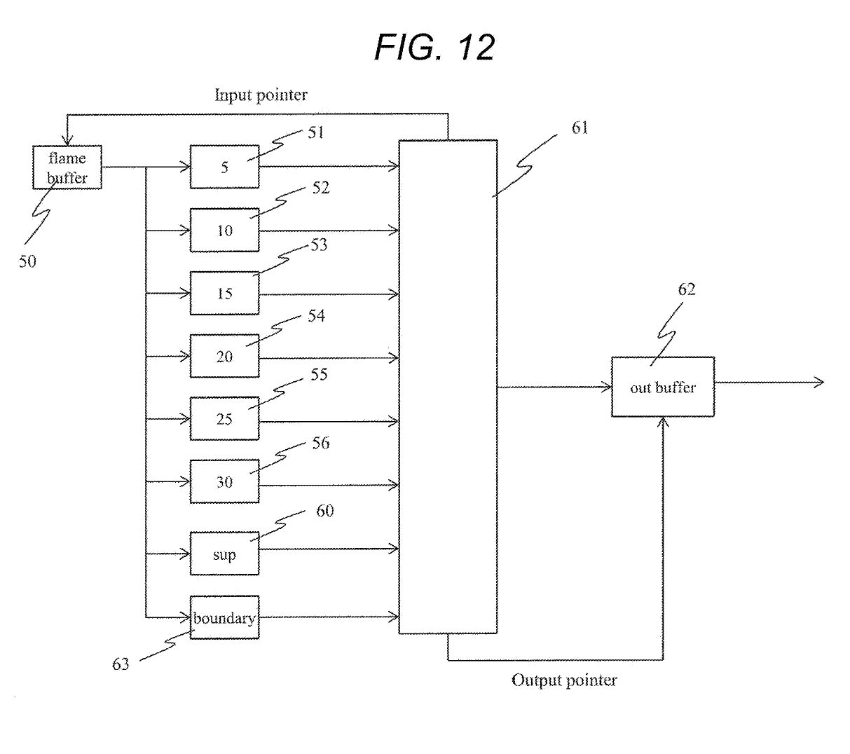

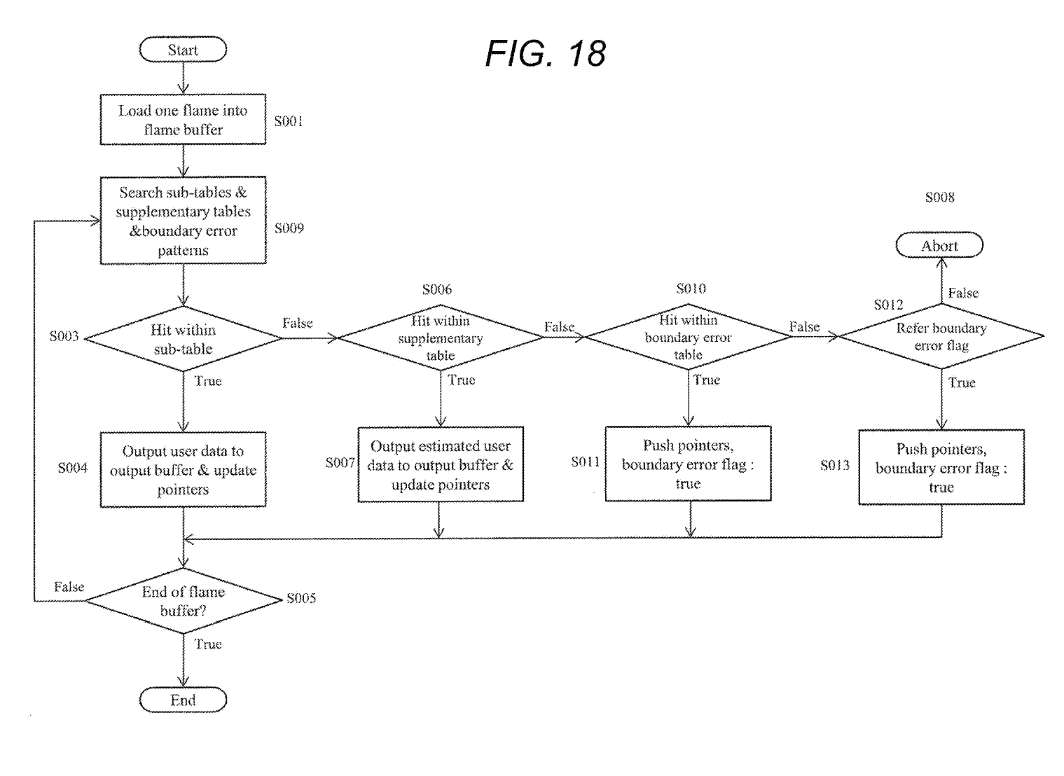

The process in the case where the demodulation error is generated due to the burst error will be described next with reference to FIGS. 12 and 18. In this case as well, the result of the PRML decoding is read into the frame buffer for each frame to execute the demodulation process (S001). As in the previous case, a channel bit stream with a necessary length is transmitted to each retriever holding a conversion table, a supplementary pattern comparator, and a boundary error pattern comparator 63, and a conversion table is retrieved (S009). However, the retrieval result is different due to the burst error. In the example in FIG. 10, if there is no error, the 30-bit retriever is expected to find out the matching pattern. However, in this example, 10-bit “00000 10000” is hit by the retrieval, thereafter, the boundary error is propagated, and then, a pattern that cannot be demodulated is found out on a demodulation error generating position 35. Thus, the demodulation error occurs. In this case, a channel bit stream with a necessary length is simultaneously transmitted to the boundary error pattern comparator 63 to compare the channel bit stream to each boundary error pattern. When the inputted pattern matches one of the boundary error patterns held by the boundary error pattern comparator (S010), the boundary error pattern comparator sets a flag indicating a match, and at the same time, stores the value of the input pointer at that time (in FIG. 10, a boundary error pattern detection position 34) (S011). However, neither the notification to the controller nor the output to the output buffer is executed. This is because, as understood from FIG. 10, it cannot be determined whether the false channel word is detected or not only by the match detected by the boundary error pattern comparator. Thereafter, the demodulation error is detected on the demodulation error generating position 35 after the boundary error pattern detection position. Specifically, this is the case where the determination of false is made in S010.

After the demodulation error is detected, the controller refers to the status of the boundary error pattern comparator (S012). When the boundary error pattern detection flag is set on the boundary error pattern comparator, the controller tries to perform the recovery process (S013). Specifically, when the demodulation error is detected, and the boundary error pattern detection flag is set, the controller determines that the burst error occurs before the burst error boundary error pattern detection position. The controller performs the recovery process by referring to the content of the boundary error pattern comparator. Firstly, the controller returns the value of the input pointer to the value thereof upon the detection of the boundary error pattern stored in the boundary error pattern comparator. The controller also returns the value of the output pointer to the value corresponding to the value of the input pointer. Then, the controller outputs the user bit stream associated with the detected boundary error pattern to the output buffer. Next, the controller updates the values of the input pointer and the output pointer according to the length of the detected boundary error pattern. Thus, the recovery process is ended. As a result of the recovery process, the system is recovered from the demodulation error, and can restart the succeeding demodulation. The outputted user bit pattern is replaced by the one that is considered to be more correct.

(Pattern Limitation, Pattern Replacement)

In general, the shortest mark having small resolution is liable to cause an error, and when there are a series of the shortest marks, a burst error is likely to occur. In view of this, the number of consecutive 5T marks is limited to be not more than a certain number of times, as described in JP-2003-273743-A. However, as stated in the background art, under the condition in which the run-length limit code of d=4 is used, and the linear recording density is enhanced before the resolution of 5T mark becomes 0, a pattern including not only the 5T mark but also a 6T mark might cause an error. A pattern having many consecutive 5T marks or 6T marks might cause an extremely long burst error.

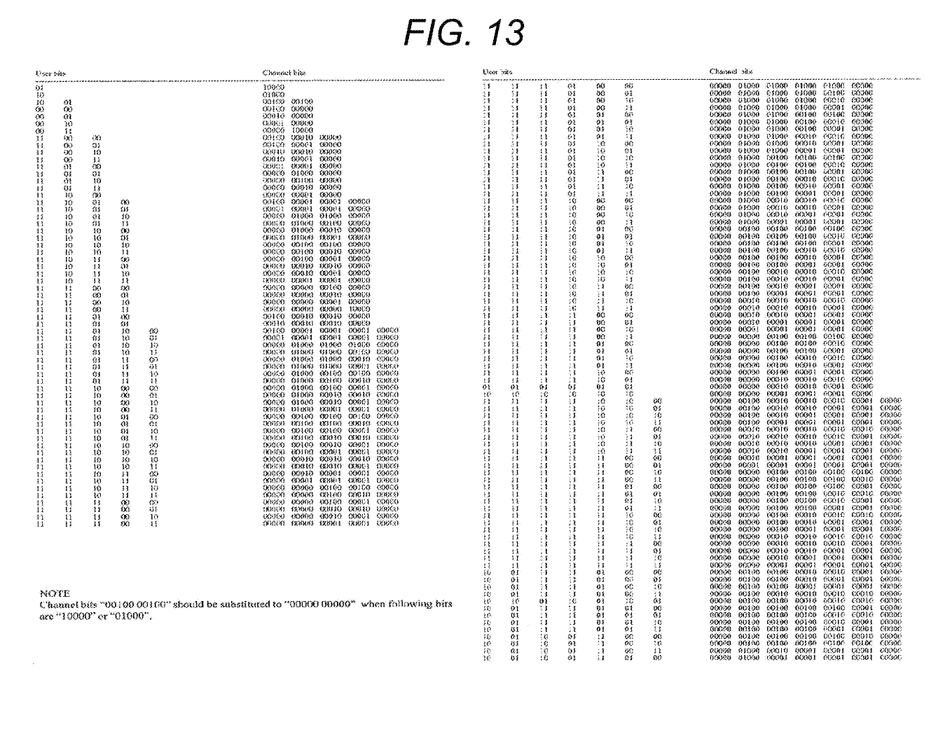

In general, in the VFM system, a pattern having plural consecutive 5T marks or 6T marks occurs by consecutive short channel words. This is ultimately inevitable. However, when a long channel word including plural 5T marks or 6T marks is linked to such pattern, the resultant pattern might become a potential cause of an extremely long burst error. In order to reduce the above-mentioned condition as much as possible, the present invention implements a pattern selection and pattern replacement focusing on non-consecutive short mark (5T or 6T). FIG. 13 illustrates a conversion table obtained as a result of the pattern selection and pattern replacement.

The pattern selection method will firstly be described. This can be restated as a selection basis as to which element (pattern) is used from a channel bit stream candidate set upon creating a conversion table. Here, the state in which consecution of short marks is interrupted in a mark of 7T or more is defined as a basis. Specifically, the channel word with the channel word length of 25 bits or more is limited to the one starting with “00000” and ending with “00000” except for some exceptions. The exceptions include “00100 00001 00001 00001 00000” and “00001 00001 00001 00001 00000”. However, in the former pattern, the space between the first “1” and the next “1” is 6T, i.e., 7T in the NRZI format, so that the interruption of the consecution of the short marks can be realized. As is understood from FIG. 13, two or more “0”s are consecutive at the end of all channel bit patterns. The first “1” in the latter pattern becomes the terminal end of the mark of 7T or more, so that the interruption of the consecution of the short marks can also be realized. The patterns with the channel word length of 30 bits or more are limited to those starting with “00000” and ending with “00000”. Thus, except for the exception, the channel word with the length of 25 bits or more starts with the mark of 9T or more on at least its front part. Specifically, the consecution of the short marks can be interrupted.

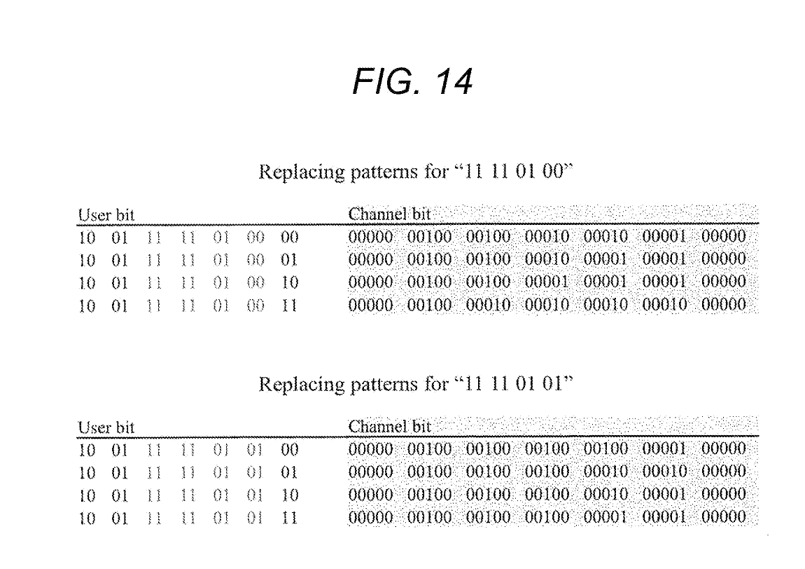

Next, the pattern replacement will be described. A pattern starting with “00000” and ending with “00000” is selected as much as possible for the pattern with a channel word length of 20 bits or more. However, the number of the channel bit stream candidates with the length of 20 bits is limited. Therefore, when the pattern is limited to the one starting with “00000” and ending with “00000”, the conversion table afterward does not converge. Therefore, some patterns do not satisfy the above condition. As for “00100 00001 00001 00000” and “00001 00001 00001 00000” out of the patterns, the consecution of the short marks can be interrupted by the reason same as the reason for the exception pattern with 25-bit length. However, as for “00100 00010 00010 00000” and “00010 00010 00010 00000”, the consecution of the short marks from the head cannot be interrupted at the front part of the pattern. Therefore, the pattern is replaced by utilizing a pattern with a channel word length of 35 bits having sufficient excess pattern, in order to solve this problem. FIG. 14 illustrates this portion in the conversion table. This example shows the case where “00100 00100” to which the short marks might be linked is present just before the pattern in which the short marks might be consecutive. The pattern with 30-bit length is replaced by a combination of a 20-bit pattern and 10-bit pattern. However, since the one that can actually be utilized is a 35-bit pattern, the pattern for the replacement is more redundant than the original pattern by 5 channel bits, i.e., 2 user bits. In order to fill this redundancy, 2 bits are added to the end of the user bit pattern corresponding to the replaced pattern, whereby four pairs of conversions are prepared for each of “00100 00010 00010 00000” and “00010 00010 00010 00000”.

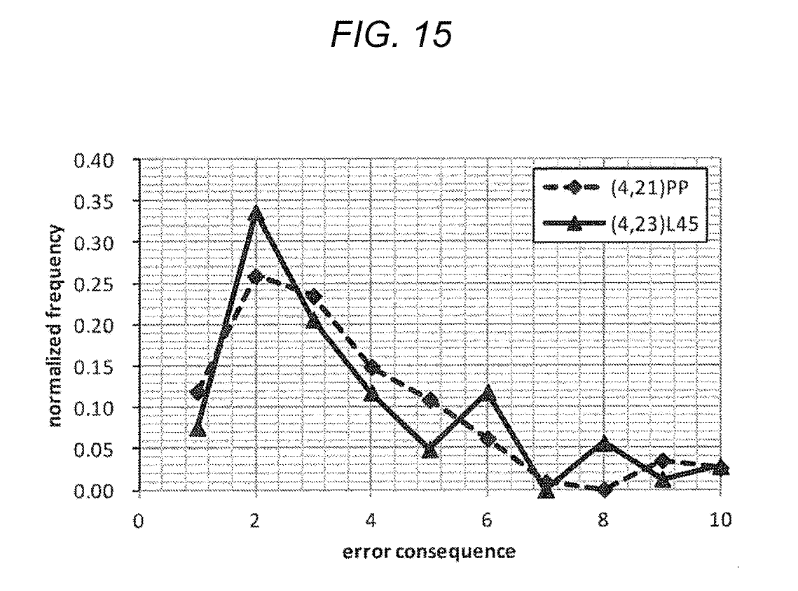

FIG. 15 is a graph formed such that a random bit stream is modulated by using the conversion table created as described above, and the distribution of the length of the observed burst error is illustrated by performing the reproduction simulation same as that in FIG. 4. For comparison, the result of using (4, 21) PP is also illustrated. It is found that, as a whole, the burst error with the short burst length increases, and the burst error with the long burst length decreases.

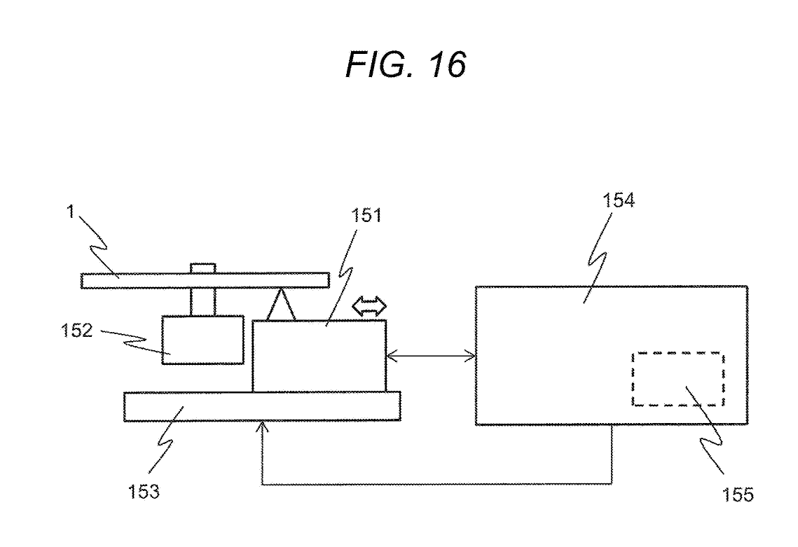

FIG. 16 illustrates one example of a configuration of an optical disk device. An optical disk 1 is rotated by a spindle motor 152. An optical pickup 151 includes an optical system having a light source, an objective lens, and other components used for recording and reproduction. The optical pickup performs seek by a slider 153. The seek and the rotation of the spindle motor are executed by an instruction from a main circuit 154. The main circuit is provided with a dedicated processing system including a code modulation/demodulation circuit, a signal processing circuit, and a feedback controller, a microprocessor, and a memory. Firmware 155 controls the overall operation of the optical disk device. The firmware is stored in the memory in the main circuit.

What is claimed is:

1. A modulation/demodulation method using a run-length limit coding rule, the method comprising:
modulating user data with a predetermined code modulation format; and
demodulating a decoded signal string, wherein
a correspondence to a channel bit stream set element from an optional user bit stream set element is unique in a conversion table that is referred to during the modulation, and
a conversion table that is referred to during the demodulation includes plural correspondence source elements to at least some user bit stream set elements, and at least one of them is asymmetric with respect to the conversion table referred to during the modulation.

2. The modulation/demodulation method according to claim 1, wherein one of the correspondence source elements is a channel bit stream, and is generated by a burst shift from the channel bit stream, in the conversion table referred to during the demodulation.

3. The modulation/demodulation method according to claim 2, wherein the bit stream generated by the burst shift is a bit stream in which plural edges are shifted by one bit in the same direction.

4. The modulation/demodulation method according to claim 1, wherein the correspondence to the user bit stream is defined in the conversion table referred to during the demodulation.

5. The modulation/demodulation method according to claim 1, wherein
when a demodulation error occurs during the demodulation,
the channel bit stream having a predetermined length and a boundary error pattern held beforehand are compared, and when they match, a return process is executed.

6. A demodulation apparatus for demodulating a channel bit stream, which is modulated based upon a run-length limit rule, to a user data stream, the apparatus comprising:
a unit that determines whether or not the channel bit stream matches a channel bit stream necessary for the demodulation;
a unit that detects whether or not the channel bit stream matches a bit stream generated from plural designated channel bit streams;
a unit that detects a demodulation error; and
a unit that replaces an output data bit based upon the demodulation error detection unit, the unit detecting whether the channel bit stream matches the bit stream generated from the plural designated channel bit streams, and the determination result.

7. The demodulation apparatus according to claim 6, wherein the bit stream generated from the channel bit stream is a bit stream in which plural edges are shifted in the same direction by one bit.

8. A code modulation method in which the minimum run-length is 4, wherein at least 5 bits from the head and at least 5 bits from the end of a channel word having a length of 30 bits or more are “0”.
